(19) United States
(12) Patent Application Publication
(10) Pub. No.: US 2019/0339613 A1
(43) Pub. Date: Nov. 7, 2019

(54) Photosensitive Material For Lift-Off Applications

(71) Applicants: Jeremy Golden, Burlington, MA (US); Gerard Gomes, West Boylston, MA (US); Roger Sinta, Woburn, MA (US); Sha Liu, Frisco, TX (US); Michael Cronin, Norfolk, MA (US)

(72) Inventors: Jeremy Golden, Burlington, MA (US); Gerard Gomes, West Boylston, MA (US); Roger Sinta, Woburn, MA (US); Sha Liu, Frisco, TX (US); Michael Cronin, Norfolk, MA (US)

(21) Appl. No.: 16/404,234

(22) Filed: May 6, 2019

Related U.S. Application Data
(60) Provisional application No. 62/668,212, filed on May 7, 2018.

(51) Int. Cl. G03F 7/004; G03F 7/038

(52) U.S. Cl. CPC G03F 7/0045; G03F 7/038

(57) ABSTRACT

Disclosed herein is a photosensitive composition that includes: a novolak polymer; one or more crosslinkers; photoacid generator; and a hydroxybenzophenone compound having the general structure (I) wherein m is 0 to 3 and n is 0 to 4 and m+n may be 0 to 5

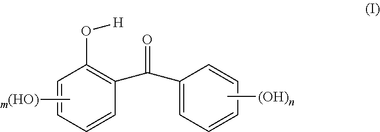

The present application for patent claims the benefit of U.S. Provisional Patent Application No. 62/668,212, entitled Photosensitive Material For Lift-Off Applications, filed 7 May 2018; which application is incorporated herein by reference.

### FIELD OF THE INVENTION

The present application for patent relates to a light-sensitive photosensitizer composition especially useful for lift-off applications.

### BACKGROUND

Photoresist compositions are used in microlithography processes for making miniaturized electronic components such as in the fabrication of integrated circuit devices. Generally, in these processes, a coated film of a photoresist composition is applied to a substrate such as silicon wafers used for making integrated circuits, circuit boards and flat panel display substrates. The coated substrate is then baked to evaporate any solvent in the film and to fix the coating onto the substrate. The baked coated surface of the substrate is next subjected to an image-wise exposure of actinic radiation.

This actinic radiation exposure causes a chemical transformation in the exposed areas of the coated surface. Visible light, ultraviolet (UV) light, extreme ultraviolet (EUV), electron beam and X-ray radiant energy are radiation types commonly used today in microlithographic processes. After this image-wise exposure, the coated substrate is treated with a developer solution to dissolve and remove either the radiation-exposed areas (for positive-type resists) or the unexposed areas (for negative-type resists) of the coated surface of the substrate.

After this development operation, the now partially unprotected substrate may be treated with a substrate-etchant solution, plasma gases or reactive ions, or have metal or metal composites deposited in the spaces of the substrate where the photoresist coating was removed during development. The areas of the substrate where the photoresist coating still remains are protected. Later, the remaining areas of the photoresist coating may be removed during a stripping operation, leaving a patterned substrate surface. In some instances, it is desirable to heat treat the remaining photoresist layer, after the development step and before the etching step, to increase its adhesion to the underlying substrate.

The Lift-off process differs from the normal photoresist process. First, the substrate is prepared by cleaning, drying, adhesion promotion, or other means. Next, a sacrificial layer of a photosensitive material is deposited and an inverse pattern is created, preferably with an inverted resist profile, such as with a negative-working photoresist. As above, various exposure methods can be used, such as visible light, ultraviolet (UV) light, extreme ultraviolet (EUV), electron beam and X-ray radiant energy. The type of exposure will influence the selection of the suitable photosensitive material. In negative-working resists, the photoresist is removed in the unexposed areas, where the target material is to be located, creating an inverse pattern. Preferably, the top of the resist feature is wider than the bottom; such that the pattern profile is inverted. This inverted profile will mask the target material from the substrate and leave the exposed photoresist open to a later applied resist stripper or remover. The target material (usually a thin metal layer) is deposited on the whole surface of the patterned wafer, including the remaining photoresist as well as the parts of the wafer were the resist was developed away. The remaining patterned resist material and the target material on top of it is then stripped away, leaving the target material on the substrate in the desired pattern.

Lift-off processing is particularly useful in the manufacture of patterned structures, such as in wafer level packaging, displays, light emitting diode applications or microelectromechanical systems, electrochemical deposition of electrical interconnects has been used as the interconnect density increases. In many of these applications, cost has become a factor in providing materials that meet engineering targets without unnecessary expense.

Known negative-working photosensitive materials used in lift-off processing may employ an absorbing dye that suppresses substrate reflections. Such reflections can interfere with the integrity of the pattern. In addition, the dye can aid in the formation of an inverted profile that will mask the target material effectively. Known photosensitive materials that are sensitive in the near ultraviolet range have used dyes such as curcumin, dye and azo dyes such as Sudan Red or Sudan Orange. However, curcumin is a plant-based natural product, which may have impurities; the removal of which requires additional expense. Moreover, the absorbance properties of curcumin vary because of its ability to assume different tautameric configurations which may depend on trace acids or bases in the photosensitive composition. Finally, the solubility of curcumin may not be sufficient to provide enough absorbance in the resist film. Azo dyes frequently have impurities that comprise disubstituted azo linked aromatic groups. Indeed, the absorbance of such dyes in the Near UV may depend on the level of such impurities.

Therefore, there remains a need for a negative working photosensitive material that exhibits high photosensitivity, even in thick film applications, generates reproducible inverted profiles for lift-off applications, promotes dissolution of the unexposed or partially exposed photoresist and strips without leaving residue. The above referenced needs are addressed by the invention described herein.

### BRIEF DESCRIPTION OF THE FIGURES

FIG. 1 shows resist profiles for various additives as described in Example 1, infra.

FIG. 2 shows resist profiles with high levels of curcumin and tetrahydroxy benzophenone as described in Example 2, infra.

FIG. 3 shows the formulation of FIG. 1 with various feature sizes.

### DETAILED DESCRIPTION

As used herein, the conjunction “and” is intended to be inclusive and the conjunction “or” is not intended to be exclusive unless otherwise indicated. For example, the phrase “or, alternatively” is intended to be exclusive. The conjunction “or” may also be exclusive when required by context. As used herein, novolak polymers are condensation products of phenolic compounds and aldehydes such as formaldehyde, acetaldehyde or substituted or unsubstituted benzaldehydes or condensation products of phenolic compounds and substituted or unsubstituted methylol compounds. As used herein, cresylic novolak polymers are novolak polymers that comprise cresol repeat units. As used herein, the adjective, “exemplary” is intended to indicate an example without indicating preference.

Disclosed herein is a photosensitive composition that includes: a novolak polymer; one or more crosslinkers; photoacid generator; and a hydroxybenzophenone compound having the general structure (I) wherein m is 0 to 3 and n is 0 to 4 and m+n may be 0 to 5

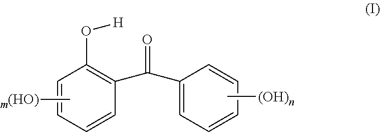

In accordance with the above embodiments, photoacid generators are present to generate acid upon exposure to actinic irradiation. Such photoacid generators can be present alone or in admixture and may be selected in accordance with their ability to generate acid using radiation of a particular wavelength, wavelength range, energy or energy range. Without intending to be bound by theory, it is thought that photoacid generators produce acids by different mechanisms. Accordingly, photoacid generators may be present at selected concentrations, alone or in admixture, to optimize acid output for the selected form of actinic irradiation.

For example, photoacid generators may be present in the solid resist film at concentrations from about 1 μmole/g of resist solids to about 1,000 μmole/g (micromoles per gram) of resist solids. As a further example, photoacid generators may be present in the solid resist film at concentrations from about 5 μmole/g of resist solids to about 300 μmole/g of resist solids. As a still further example, photoacid generators may be present in the solid resist film at concentrations from about 10 μmole/g of resist solids to about 150 μmole/g of resist solids. As a still further example, photoacid generators may be present in the solid resist film at concentrations from about 15 μmole/g of resist solids to about 100 mole/g of resist solids.

Photoacid generators may have different chemical compositions. For example, without limitation, suitable photoacid generators may be onium salts, dicarboximidyl sulfonate esters, oxime sulfonate esters, diazo(sulfonyl methyl) compounds, disulfonyl methylene hydrazine compounds, nitrobenzyl sulfonate esters, biimidazole compounds, diazomethane derivatives, glyoxime derivatives, β-ketosulfone derivatives, disulfone derivatives, nitrobenzylsulfonate derivatives, sulfonic acid ester derivatives, imidoyl sulfonate derivatives, halogenated triazine compounds, equivalents thereof or combinations thereof.

Onium salt photoacid generators may comprise, without limitation, alkyl sulfonate anions, substituted and unsubstituted aryl sulfonate anions, fluoroalkyl sulfonate anions, fluoarylalkyl sulfonate anions, fluorinated arylalkyl sulfonate anions, hexafluorophosphate anions, hexafluoroarsenate anions, hexafluoroantimonate anions, tetrafluoroborate anions, equivalents thereof or combinations thereof.

Specifically, without limitation suitable photoacid generators may include triphenylsulfonium trifluoromethanesulfonate, triphenylsulfonium nonafluoro-n-butanesulfonate, triphenylsulfonium perfluoro-n-octanesulfonate, and triphenylsulfonium 2-(bicyclo[2.2.1]heptan-2-yl)-1,1,2,2-tetrafluoroethanesulfonate, 4-cyclohexylphenyldiphenylsulfonium trifluoromethanesulfonate, 4-cyclohexylphenyldiphenylsulfonium nonafluoro-n-butanesulfonate, 4-cyclohexylphenyldiphenylsulfonium perfluoro-n-octanesulfonate, 4-cyclohexylphenyldiphenylsulfonium 2-(bicyclo[2.2.1]heptan-2-yl)-1,1,2,2-tetrafluoroethanesulfonate, 4-methanesulfonylphenyldiphenylsulfonium trifluoromethanesulfonate, 4-methanesulfonylphenyldiphenylsulfonium nonafluoro-n-butanesulfonate, 4-methanesulfonylphenyldiphenylsulfonium perfluoro-n-octanesulfonate, and 4-methanesulfonylphenyldiphenylsulfonium 2-(bicyclo[2.2.1]heptan-2-yl)-1,1,2,2-tetrafluoroethanesulfonate, diphenyliodonium trifluoromethanesulfonate, diphenyliodonium nonafluoro-n-butanesulfonate, diphenyliodonium perfluoro-n-octanesulfonate, diphenyliodonium 2-(bicyclo[2.2.1]heptan-2-yl)-1,1,2,2-tetrafluoroethanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, bis(4-t-butylphenyl)iodonium 2-(bicyclo[2.2.1]heptan-2-yl)-1,1,2,2-tetrafluoroethanesulfonate, 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-(bicyclo[2.2.1]heptan-2-yl)-1,1,2,2-tetrafluoroethanesulfonate, 1-(6-n-butoxynaphthalen-2-yl)tetrahydrothiophenium trifluoromethanesulfonate, 1-(6-n-butoxynaphthalen-2-6 Docket Number KL 50719-US yl)tetrahydrothiophenium nonafluoro-n-butanesulfonate, 1-(6-n-butoxynaphthalen-2-yl)tetrahydrothiophenium perfluoro-n-octanesulfonate, 1-(6-n-butoxynaphthalen-2-yl)tetrahydrothiophenium 2-(bicyclo[2.2.1]heptan-2-yl)-1,1,2,2-tetrafluoroethanesulfonate, 1-(3,5-dimethyl-4-hydroxyphenyl)tetrahydrothiophenium trifluoromethanesulfonate, 1-(3,5-dimethyl-4-hydroxyphenyl)tetrahydrothiophenium nonafluoro-n-butanesulfonate, 1-(3,5-dimethyl-4-hydroxyphenyl)tetrahydrothiophenium perfluoro-n-octanesulfonate, 1-(3,5-dimethyl-4-hydroxyphenyl)tetrahydrothiophenium 2-(bicyclo[2.2.1]heptan-2-yl)-1,1,2,2-tetrafluoroethanesulfonate N-(trifluoromethanesulfonyloxy)bicyclo[2.2.1]hept-5-ene-2,3-dicarboximide, N-(nonafluoro-n-butanesulfonyloxy)bicyclo[2.2.1]hept-5-ene-2,3-dicarboxyimide, N-(perfluoro-n-octanesulfonyloxy)bicyclo[2.2.1]hept-5-ene-2,3-dicarboxyimide, N-[2-(bicyclo[2.2.1]heptan-2-yl)-1,1,2,2-tetrafluoroethanesulfonyloxy]bicyclo[2.2.1]hept-5-ene-2,3-dicarboxyimide, N-[2-(tetracyclo[4.4.0.1^{2,5}.1^{7,10}]dodecan-3-yl)-1,1-difluoroethanesulfonyloxy]bicyclo[2.2.1]hept-5-ene-2,3-dicarboxyimide, 1,3-dioxoisoindolin-2-yl trifluoromethanesulfonate, 1,3-dioxoisoindolin-2-yl nonafluoro-n-butane sulfonate, 1,3-dioxoisoindolin-2-yl perfluoro-n-octane sulfonate, 3-dioxoisoindolin-2-yl 2-(bicyclo[2.2.1]heptan-2-yl)-1,1,2,2-tetrafluoroethanesulfonate, 3-dioxoisoindolin-2-yl N-[2-(tetracyclo[4.4.0.1^{2,5}.1^{7,10}]dodecan-3-yl)-1,1-difluoroethanesulfonate, 1,3-dioxo-1H-benzo[de]isoquinolin-2(3H)-yl trifluoromethanesulfonate, 1,3-dioxo-1H-benzo[de]isoquinolin-2(3H)-yl nonafluoro-n-butane sulfonate, 1,3-dioxo-1H-benzo[de]isoquinolin-2(3H)-yl perfluoro-n-octanesulfonate, 1,3-dioxo-1H-benzo[de]isoquinolin-2(3H)-yl 2-(bicyclo[2.2.1]heptan-2-yl)-1,1,2,2-tetrafluoroethanesulfonate, or 1,3-dioxo-1H-benzo[de]isoquinolin-2(3H)-yl N-[2-(tetracyclo[4.4.0.1^{2,5}.1^{7,10}]dodecan-3-yl)-1,1-difluoroethanesulfonate, (E)-2-(4-methoxystyryl)-4,6-bis(trichloromethyl)-1,3,5-triazine, 2-(Methoxyphenyl)-4,6-bis-(trichloromethyl)-s-triazine, 2-[2-(Furan-2-yl)ethenyl]-4,6-bis(trichloromethyl)-s-triazine, 2-[2-(5-methylfuran-2-yl)ethenyl)-4,6-bis(trichloromethyl)-s-triazine, 2-[2-(3,4-Dimethoxyphenyl)ethenyl]-4,6-bis(trichloromethyl)-s-triazine, equivalents thereof or combinations thereof. Suitable photoacid generators may also include onium salts comprising anions and cations in combinations not shown supra.

Photoacid generators may be selected for specific wavelength ranges. Without limitation, for example, in the near UV-visible range (300 nm-440 nm), it is known in the art that naphthalene dicarboximidyl triflate (NIT) (1,3-dioxo-1H-benzo[de]isoquinolin-2(3H)-yl trifluoromethanesulfonate) (IV) and other imide esters such as (V) and VIII) are useful. In addition, onium salts such as (III) may be used advantageously, as well as oxime sulfonic acid ester such as (II), (VI), and (VII). The abbreviation OA represents a sulfonate group having alkyl, aryl, fluoroalkyl such as —CF₃, —C₄F₉, —C₈F₁₇, or fluoroaryl substituents.

Photoacid generators may be present as 0.5%-15% of total resist solids. As a further example, PAGs may be present as 1%-10% of total resist solids.

The photosensitive composition disclosed herein may also comprise photosensitizers that extend the effective wavelength and/or energy range. Such photosensitizers may be, without limitation, substituted and unsubstituted anthracenes, substituted and unsubstituted phenothiazines, substituted and unsubstituted perylenes, substituted and unsubstituted pyrenes, and aromatic carbonyl compounds, such as benzophenone and thioxanthone, fluorene, carbazole, indole, benzocarbazole, acridone chlorpromazine and the like, or combinations of any of the foregoing. Sensitizers may be present as 0.5%-10% of total resist solids. As a further example, sensitizers may be present as 1%-6% of total resist solids.

Novolak polymers comprise repeat units having bridges and phenolic compounds. Suitable phenolic compounds include, without limitation, phenols, cresols, substituted and unsubstituted resorcinols, xylenols, substituted and unsubstituted benzene triols and combinations thereof. Novolak polymers are produced, usually, with an acid catalyst, by condensation polymerization of phenolic compounds and aldehydes such as formaldehyde, acetaldehyde or substituted or unsubstituted benzaldehydes or condensation products of phenolic compounds and substituted or unsubstituted methylol compounds. Bridges described supra may comprise methylene groups or methyne groups. Novolak polymers can also be made as condensation products of ketones such as acetone, methyl ethyl ketone, acetophenone and the like. Catalysts may include Lewis acids, Brønstead acids, dicationic and tricationic metal ions and the like. For example, without limitation, aluminum chloride, calcium chloride, manganese (II) chloride, manganese (III) chloride, oxalic acid, hydrochloric acid, sulfuric acid, methane sulfonic acid trifluoromethane sulfonic acid or combinations comprising any of the foregoing may be used.

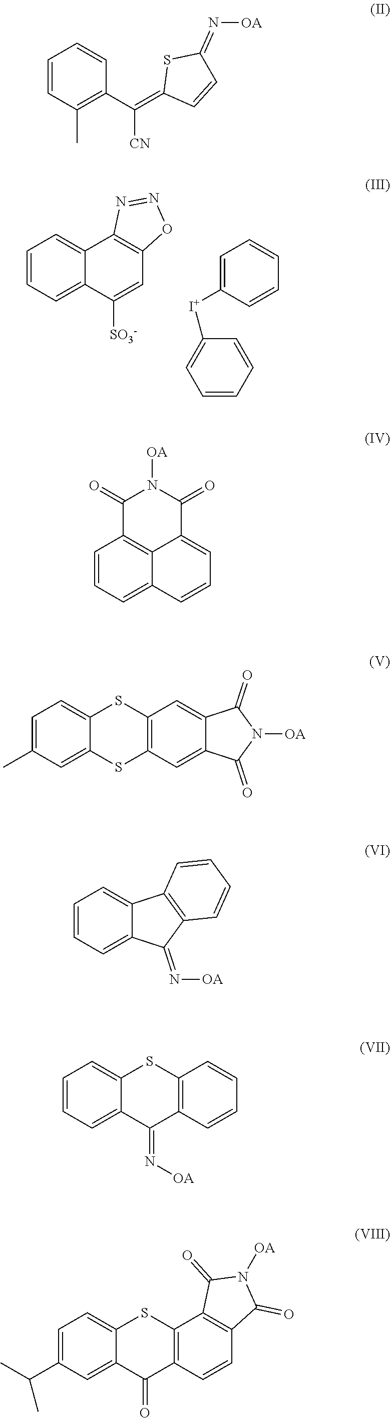

Examples of suitable novolak polymers include those obtained by the condensation reaction between a phenolic compound such as phenol, o-cresol, m-cresol, p-cresol, 2-5-xylenol and the like with an aldehyde compound such as formaldehyde in the presence of an acid or multivalent metal-ion catalyst. An exemplary weight average molecular weight for the alkali-soluble novolak polymer may be in the range from 500 to 30,000 Daltons. A further exemplary weight average molecular weight may be from 1,000 to 20,000 Daltons. A still further exemplary weight average molecular weight may be from 1,500 to 10,000 Daltons. Exemplary bulk dissolution rates for novolak polymers in 2.38% aqueous tetramethylammonium hydroxide are 10 Å/sec (Angstrom units per second) to 15,000 Å/sec. Further exemplary bulk dissolution rates are 100 Å/sec to 10,000 Å/sec. Still further exemplary bulk dissolution rates are 200 Å/sec to 5,000 Å/sec. A still further exemplary bulk dissolution rate of 1,000 Å/sec may be obtained from a single novolak polymer or a blend of novolak polymers, each comprising m-cresol repeat units.

Exemplary cresylic novolak polymers may comprise, in cresol mole percentage terms, 0%-60% p-cresol, 0%-20% o-cresol, and 0%-80% m-cresol. Further exemplary cresylic novolak polymers may comprise 0%-50% p-cresol, 0%-20% o-cresol, and 50%-100% m-cresol. Repeat units in novolak polymers are defined by the composition of the polymer, so that, for example, p-cresol may be introduced by polymerization with an aldehyde or by dimethylol-p-cresol. Moreover, cresylic novolak polymers may contain other phenolic compounds such as phenol, xylenols, resorcinols, benzene triols and the like. Further, novolak polymers can be branched or linear and may be blended to achieve a selected repeat unit mole percentage or dissolution rate. Bulk dissolution rates may be measured by the following procedure: (1) A 1-3 μm (micrometer) film of the novolak resin is spin-coated from a solution on a silicon wafer and soft baked at 110° C. for 120 seconds on a contact hot plate. (2) The film thickness is measured using an optical method such as interferometry or elipsometry or a mechanical profilometer. (3) The coated wafer is immersed in a solution of TMAH developer and the time to dissolve completely the novolak film (0 is detected visually or by means of optical inteferometry (for example, a dissolution rate monitor). The bulk dissolution rate is calculated dividing the film thickness by t_{c}.

Polymers having the general composition (I) may comprise (meth) acrylic repeat units as well as substituted or unsubstituted styrene units. Accordingly, R₁-R₅ may, independently, be either —H or —CH₃.

The photosensitive resin composition disclosed herein may be used in the form of a solution prepared by dissolving the above described ingredients in a suitable organic solvent. Examples of suitable organic solvents include ketones such as acetone, methyl ethyl ketone, cyclohexanone, methyl isoamyl ketone, methyl amyl ketone, and the like, polyhydric alcohols and derivatives thereof such as monomethyl, monoethyl, monopropyl, monobutyl and monophenyl ethers of ethyleneglycol, ethyleneglycol monoacetate, diethyleneglycol, diethyleneglycol monoacetate, propyleneglycol, propyleneglycol monoacetate, dipropyleneglycol or dipropyleneglycol monoacetate and the like, cyclic ethers such as dioxane, tetrahydrofuran and the like, esters such as methyl lactate, ethyl lactate, methyl acetate, ethyl acetate, butyl acetate and the like and solvents having aromatic groups such as anisole, ethyl benzene, xylenes, chlorobenzene, toluene and the like. These organic solvents can be used either singly or in admixture according to need. Novolak polymers may be present as 10% to 95% of total resist solids. As a further example, novolak polymers may be present as 20% to 90% of total resist solids. As a further example, novolak polymers may be present as 50% to 90% of total resist solids.

Other optional additives, which have compatibility with and can be added to the composition disclosed and claimed herein according to need, include auxiliary resins, plasticizers, surface leveling agents and stabilizers to improve the properties of the resist layer, coloring agents to increase the visibility of the patterned resist layer formed by development, antihalation dyes, and the like.

The procedure for the preparation of a patterned resist layer by using the photosensitive composition disclosed herein can be conventional. For example, a substrate such as a semiconductor silicon wafer is evenly coated with the photosensitive composition in the form of a solution by using a suitable coating machine such as a spin-coater followed by baking in a convection oven or on a hotplate to form a resist layer which is then exposed pattern-wise to actinic radiation such as deep ultraviolet light, near ultraviolet light, or visible light emitted from low-pressure, high-pressure and ultra-high-pressure mercury lamps, arc lamps, xenon lamps and the like through a photomask bearing a desired pattern on a minifying light-projection exposure apparatus and electron beams scanned in accordance with a desired pattern to build up a latent image of the pattern in the resist layer. Thereafter, the latent image in the resist layer may optionally be baked in a convection oven or on a hotplate, developed using an alkaline developer solution such as an aqueous solution of tetra (C1-C4 alkyl) ammonium hydroxide, choline hydroxide, lithium hydroxide, sodium hydroxide, or potassium hydroxide, for example, tetramethyl ammonium hydroxide, in a concentration of 1 to 10% w/w, to yield a patterned resist layer having good fidelity to the pattern of the photomask.

Thicknesses may range from 20 nm to 100 μm. To achieve these thicknesses, a combination of different spin speeds and total solids concentrations may be employed. Depending on the size of the substrate, spin speeds of from 500 rpm to 10,000 rpm may be used. Concentration may be expressed as a percentage w/w of total solids in the photosensitive composition. Without limitation, an exemplary total solids percentage w/w is from 0.05% to 65%. Without limitation, a further exemplary total solids percentage w/w is from 20% to 60%. Without limitation, a further exemplary total solids percentage w/w is from 40% to 55%.

Crosslinkers, suitable for the current disclosure, comprise compounds able to cross-link with the above disclosed ester, after it is deprotected, but, in any case, if either X or Y comprise functional groups that can be reacted with the crosslinker. Among these reactive functional groups are alcohols, phenols, protic amides, carboxylic acids and the like. Before the deprotection reaction occurs, at least a portion of the reactive functional groups are protected by an acid labile group described above. Once the deprotection reaction occurs, the crosslinker may react with the deprotected functional group. Not to be held to theory, it is believed that the photogenerated acid not only reacts with the acid-labile group of the above disclosed ester but aids in the reaction of the crosslinker with itself and the ester. Examples of crosslinkers include compounds comprising at least one type of substituted group that possess a cross-linking reactivity with the phenol or similar group of the on the deprotected ester. Specific examples of this crosslinking group include, without limitation, the glycidyl ether group, the oxetane group, glycidyl ester group, glycidyl amino group, methoxymethyl group, ethoxy methyl group, benzyloxymethyl group, dimethylamino methyl group, diethylamino methyl group, dimethylol amino methyl group, diethylol amino methyl group, morpholino methyl group, acetoxymethyl group, benzyloxy methyl group, formyl group, acetyl group, vinyl group and isopropenyl group.

Non limiting examples of compounds having the aforementioned cross-linking substituted group include, bisphenol A-based epoxy compounds, bisphenol F-based epoxy compounds, bisphenol S-based epoxy compounds, novolak resin-based epoxy compound, resol resin-based epoxy compounds, poly (hydroxystyrene)-based epoxy compounds, (3-ethyloxetan-3-yl)methanol, 1,3-bis(((3-ethyloxetan-3-yl)methoxy)methyl)benzene, 3,3′-oxybis(methylene)bis(3-ethyloxetane), and phenol novolak oxetane, sold by Toagosei America Inc. of West Jefferson, Ohio, as OXT-101, OXT-121, OXT-221 and PNOX1009, respectively, methylol group-containing melamine compounds, methylol group-containing benzoguanamine compounds, methylol group-containing urea compounds, methylol group-containing phenol compounds, alkoxyalkyl group-containing melamine compounds, alkoxyalkyl group-containing benzoguanamine compounds, alkoxyalkyl group-containing urea compounds, alkoxyalkyl group-containing phenol compounds, carboxymethyl group-containing melamine resins, carboxy methyl group-containing benzoguanamine resins, carboxymethyl group-containing urea resins, carboxymethyl group-containing phenol resins, carboxymethyl group-containing melamine compounds, carboxymethyl group-containing benzoguanamine compounds, carboxymethyl group-containing urea compounds, and carboxymethyl group-containing phenol compounds, methylol group-containing phenol compounds, methoxymethyl group-containing melamine compounds, methoxymethyl group-containing phenol compounds, methoxymethyl group-containing glycol-uril compounds, methoxymethyl group-containing urea compounds and acetoxymethyl group-containing phenol compounds. The methoxymethyl group-containing melamine compounds are commercially available as, for example, CYMEL300, CYMEL301, CYMEL303, CYMEL305 (manufactured by Mitsui Cyanamid), the methoxymethyl group-containing glycol-uril compounds are commercially available as, for example, CYMEL1170 and CYMEL1174 (manufactured by Mitsui Cyanamid), and the methoxymethyl group-containing urea compounds are commercially available as, for example, MX290 (manufactured by Sanwa Chemicals).

The hydroxybenzophenone compound (I) may function both as an absorbing chromophore and as a dissolution promoter. Without intending to be bound by theory, it is believed that a -hydroxy substituent on the “2” position of either of the aromatic rings allows the phenolic hydrogen atom to hydrogen bond to the carbonyl oxygen. This increases the absorbance in the near UV. Further substitution provides sufficient numbers of crosslinkable phenolic groups to create a matrix that is insoluble in developer in the exposed areas while enhancing dissolution in the unexposed or lightly exposed areas. Exemplary hydroxy benzophenone compounds include, without limitation, 2,2′-dihydroxybenzophenone, 2,3′-dihydroxybenzophenone, 2,4′-dihydroxybenzophenone, 2,3,4-trihydroxybenzophenone, 2,4,4′-trihydroxybenzophenone, 2,3,4,4′-tetrahydroxybenzophenone, 2,2′,4,4′-tetrahydroxybenzophenone, 2,3,4,2′,4′-pentahydroxybenzophenone, 2,3,4,2′,3′,4′-hexahydroxybenzophenone or a combination thereof. The hydroxybenzophenone compound may be present as a function of the percentage of total resist solids in an exemplary range from about 0.5% to about 15%. A further exemplary range may be from about 1% to about 10%. A further exemplary range may be from about 2.5% to about 6%. 2,3,2′,4′-tetrahydroxybenzophennone and 2,3,4,2′,3′,4′-hexahydroxy benzophenone have solubility in propylene glycol methyl ether acetate (PGMEA) greater than 20%, compared to curcumin, whose solubility in PGMEA is about 2.5%.

### EXAMPLES

General Preparation of Sample Photosensitive Materials:

In the following examples, components include (unless otherwise noted): solvent for film casting, novolak resin of weight averaged molecular weight, M_{w}, of 3000-3500 Daltons having a meta/para cresol ratio of 40:60 and a dissolution rate of 900 Å/sec (Angstroms per second) in standard 0.262N TMAH developer, PAG (photo acid generator), crosslinker, absorber (2,4,2′,4′-hydroxybenzophenone), and surface leveling modifiers. Absorbers (such as 2,4,2′,4′-tetrahydroxybenzophenone) may be obtained from Sigma Aldrich. The photoacid generator may be obtained from Midori. Propylene glycol methyl ether acetate, PGMEA, may be obtained from Sigma Aldrich.

### Preparation Example 1

Into a clean glass jar were charged 280.8 g of novolak polymer, 24 g of 1,3,4,6-tetrakis(methoxymethyl)glycoluril crosslinker, 12 g of 2,4,2′,4′-tetrahydroxybenzophenone absorber, 1,3-dioxo-1H-benzo[de]isoquinolin-2(3H)-yltrifluoromethanesulfonate as PAG, 3.36 g of a 10% solution of N²,N²,N⁴,N⁴,N⁶,N⁶-hexakis(methoxymethyl)-1,3,5-triazine-2,4,6-triamine in PGMEA, and 2.048 g of a 10% solution of Modaflow in PGMEA. The jar containing all ingredients was rolled on a jar mill roller for several hours until all ingredients were dissolved. The resulting solution was filtered into a clean container using a glass fiber membrane filter having a pore size of 1 μm (micron).

### Preparation Example 2

Same as Preparation example 1 except that the absorber is 2,3,4,2′,3′,4′-hexahydroxybenzophenone (HHBP).

### Preparation Example 3

Same as Preparation example 1 except that the absorber is curcumin dye.

### Preparation Example 4

Same as Preparation example 1 except that no absorber is added. In place of the absorber, 2.04 g of PGMEA were added.

### Preparation Example 5

Same as Preparation example 1 except that the absorber is bis-phenol-A (BPA).

### Example 1

Various liftoff profiles were created using preparation examples 1-5, supra, along with a standard commercially available resist material, AZ nLOF 2070, available from AZ Merck to demonstrate the efficacy of 2,4,2′,4′-tetrahydroxybenzophenone (THBP) creating lift-off profile. Six-inch silicon wafers were dehydration baked on a contact hotplate at 110° C. for 90 sec and cooled to room temperature followed by a standard vapor-prime treatment with hexamethyldisilazane (HMDS). The silicon wafers were then spin-coated with the materials described supra, and baked on a 110° C. hotplate for 90 sec to give a film thickness of 7.5 μm (microns).

The films were exposed on a broadband NUV contact printer equipped with a mercury arc lamp. After exposure, the films received a post-exposure bake (110° C. for 90 sec, contact hotplate), followed by development in standard 0.26 N TMAH developer until the unexposed areas were clearly dissolved down to the substrate and a nominal feature size of 12 μm was obtained, rinsed with deionized water and spin dried.

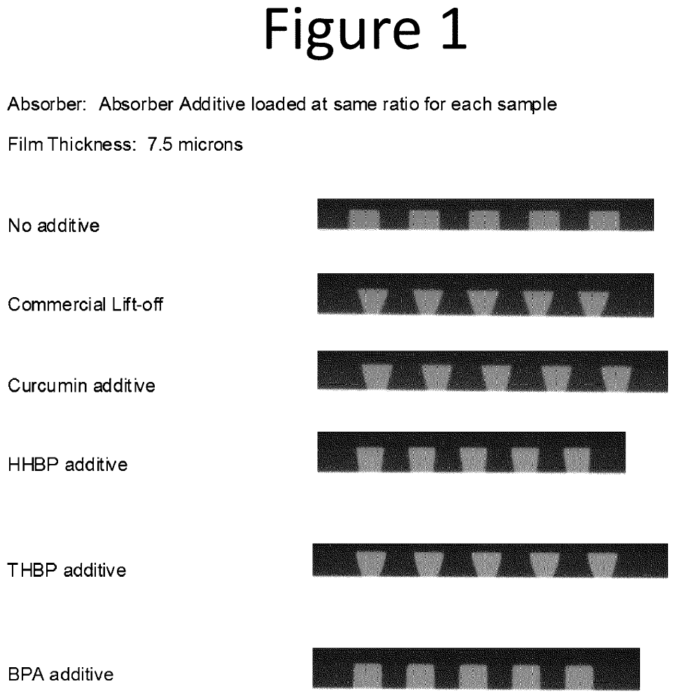

As shown in FIG. 1, films prepared with no absorber additive show straight wall profiles, consistent with film transparency at the exposing wavelength. The commercial sample, and samples prepared with curcumin, THBP, and HHBP additives demonstrate inverted profiles suitable for lift-off applications. Samples prepared with HHBP demonstrate lift-off profiles having a shallower angle that may be appropriate for thin coatings. BPA showed a straight profile, similar to that obtained with no additive.

### Preparation Examples 6-8

Same as Preparation Examples 1, 3, and 4, respectively, except that a novolak polymer of similar composition but having a weight averaged molecular weight, M_{w}, of 4500-5500 Daltons and a dissolution rate of 400 Å/sec (Angstroms per second) was used.

### Example 2

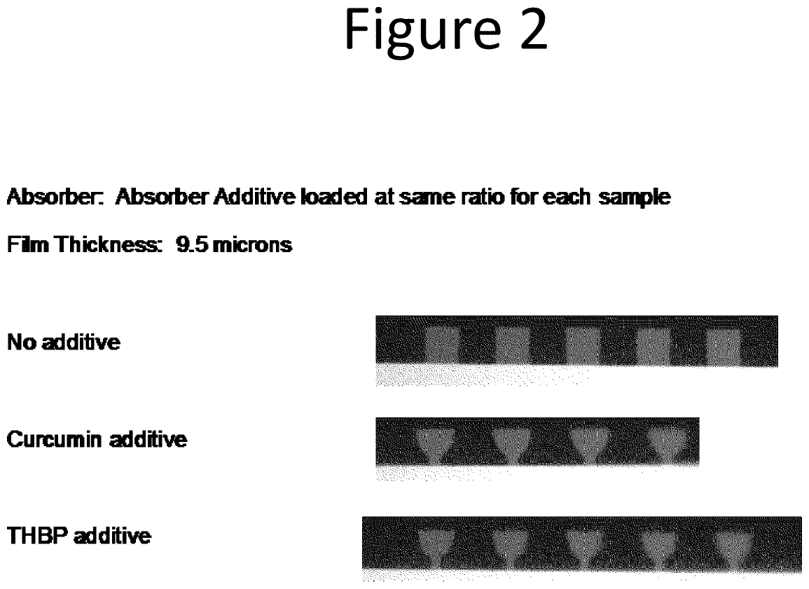

Similar to Example 1 except that formulations in Preparation Examples 6-8 were used. Films were spin coated to a thickness of 9.5 μm (microns) and lithographic features of 10 μm (microns) were printed. Results are shown in FIG. 2. Results shown indicate a straight wall profile for the sample with no absorber additive, and similar inverted profiles when curcumin or THBP are used; indicating the efficacy of THBP as an absorbing additive.

### Example 3

The present example demonstrates the ability of materials described herein to be removed from wafer substrates using ordinary solvent materials. Sample wafers were produced from the material from Preparation Example 1, according to Example 1. The samples then received a further hard bake step of hard contact on a hotplate of either 110° C. or 140° C. for 60 sec. Resist removal was tested using immersion and gentile agitation in either acetone at room temperature or N-methyl pyrrolidone at 50° C., followed by a rinse in isopropyl alcohol. Results are as shown in Table 1.

TABLE 1

| Hard Bake | | |
|---|---|---|
| (hotplate, | | |
| 60 sec) | Remover | Result |
| 110° C. | Acetone (room temperature) | Removal for all cells |
| | | demonstrated at 10 sec. |
| 140° C. | Acetone (room temperature) | Removal for all cells |
| | | demonstrated at 10 sec. |
| 110° C. | N-methyl pyrrolidone (50° C.) | Removal for all cells |
| | | demonstrated at 10 sec. |
| 140° C. | N-methyl pyrrolidone (50° C.) | Removal for all cells |
| | | demonstrated at 70 sec. |

### Example 4

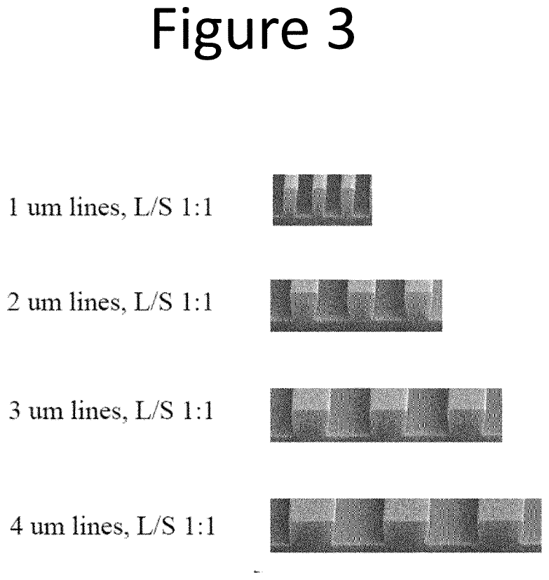

The resist of Preparation Example 1, was prepared in diluted form by adding additional PGMEA, such that a spin coated film of 2 μm (microns) of thickness could be obtained. Films of thickness, 2 μm were spin coated and exposed in a manner similar to Example 1 and results are shown in FIG. 3. Shown are feature sizes for 1 μm (micron) lines, 2 μm lines, 3 μm lines, 4 μm lines. Profiles are slightly inverted but much less so than in thicker films as seen in FIG. 1.

Although the present invention has been shown and described with reference to particular examples, various changes and modifications which are obvious to persons skilled in the art to which the invention pertains are deemed to lie within the spirit, scope and contemplation of the subject matter set forth in the appended claims.

What is claimed is:

1. A photosensitive composition comprising:
a. a novolak polymer;
b. one or more crosslinkers
c. a photoacid generator; and
d. a hydroxybenzophenone having the general structure

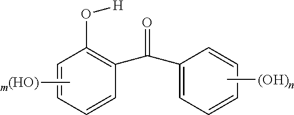

2. The photosensitive composition of claim 1, wherein the novolak polymer comprises o-, m-, or p-cresylic acid monomer repeat units or a combination thereof.

3. The photosensitive composition of claim 2, wherein the novolak polymer comprises a 2,5-xylenol monomer repeat unit.

4. The photosensitive composition of claim 1 wherein the photoacid generator is an onium salt, a dicarboximidyl sulfonate ester, an oxime sulfonate ester, a diazo(sulfonyl methyl) compound, a disulfonyl methylene hydrazine compound, a nitrobenzyl sulfonate ester, a biimidazole compound, a diazomethane derivative, a glyoxime derivative, a β-ketosulfone derivative, a disulfone derivative, a nitrobenzylsulfonate derivative, a sulfonic acid ester derivative, an imidoyl sulfonate derivative, a halogenated triazine compound, or a combination thereof.

5. The photosensitive composition of claim 3 wherein the photoacid generator is 1,3-dioxo-1H-benzo[de]isoquinolin-2(3H)-yl trifluoromethanesulfonate.

6. The photosensitive composition of claim 1 wherein the hydroxybenzophenone compound is chosen from 2,2′-dihydroxybenzophenone, 2,3′-dihydroxybenzophenone, 2,4′-dihydroxybenzophenone, 2,3,4-trihydroxybenzophenone, 2,4,4′-trihydroxybenzophenone, 2,3,4,4′-tetrahydroxybenzophenone, 2,2′,4,4′-tetrahydroxybenzophenone, 2,3,4,2′,4′-pentahydroxybenzophenone, 2,3,4,2′,3′,4′-hexahydroxybenzophenone or a combination thereof.

7. The photosensitive composition of claim 1 wherein the crosslinker comprises a methoxymethyl group, an ethoxy methyl group, a benzyloxymethyl group, a dimethylamino methyl group, a diethylamino methyl group, a dimethylol amino methyl group, a diethylol amino methyl group, a morpholino methyl group, a acetoxymethyl group, a benzyloxy methyl group, a formyl group, an acetyl group, a vinyl group, a isopropenyl group, or combinations thereof.

8. The photosensitive composition of claim 1, wherein m+n is at least 1.
